(19) United States
(12) Patent Application Publication
(10) Pub. No.: US 2024/0088181 A1
(43) Pub. Date: Mar. 14, 2024

(54) IMAGE SENSOR

(71) Applicant: Samsung Electronics Co., Ltd., Suwon-si (KR)

(72) Inventors: Jehyung Ryu, Suwon-si (KR); Hajin Lim, Suwon-si (KR); Taeksoo Jeon, Suwon-si (KR)

(21) Appl. No.: 18/454,110

(22) Filed: Aug. 23, 2023

(30) Foreign Application Priority Data
Sep. 8, 2022 (KR) 10-2022-0114457

(51) Int. Cl. H01L 27/146

(52) U.S. Cl. CPC H01L 27/1462; H01L 27/1463; H01L 27/14634; H01L 27/14636; H01L 27/14645; H01L 27/14683

(57) ABSTRACT

Provided is an image sensor including a semiconductor substrate including a first pixel and a second pixel adjacent to the first pixel, a pixel isolation structure between the first pixel and the second pixel, an anti-reflection layer on the first pixel, the second pixel, and the pixel isolation structure, and a through via structure in a through via hole that is in the anti-reflection layer and the semiconductor substrate. The through via structure may include a first conductive layer on an inner wall of the through via hole, and a second conductive layer on the first conductive layer on the inner wall of the through via hole, and the anti-reflection layer may include TiO₂, and the first conductive layer may include a material having a higher work function than Ti.

### CROSS-REFERENCE TO RELATED APPLICATION

This application is based on and claims priority under 35 U.S.C. § 119 to Korean Patent Application No. 10-2022-0114457, filed on Sep. 8, 2022 in the Korean Intellectual Property Office, the disclosure of which is incorporated by reference herein in its entirety.

### BACKGROUND

The inventive concept relates to an image sensor.

Image sensors are devices converting optical image signals into electrical signals. The image sensors may include pixel regions and logic regions. In the pixel regions, a plurality of pixels are arranged in a two-dimensional array structure, and a unit pixel constituting the pixels may include one photodiode and pixel transistors. In the logic regions, logic elements for processing pixel signals from the pixel regions may be arranged.

Recently, a back side illumination (BSI) image sensor having a structure, in which pixel regions and logic regions are formed in two separate semiconductor chips, and those two semiconductor chips are stacked, has been proposed. A bonding technology for implementing BSI image sensor may include an oxide-to-oxide process and a metal-to-metal process, and a technology of through silicon via (hereinafter, TSV) or back via stack (hereinafter, BVS) method, which is applied to those processes, has been actively researched. When an image sensor is formed using the TSV or BVS method, an isolation structure may be formed between a plurality of terminals to reduce/suppress a leakage current between the plurality of terminals. However, when the isolation structure includes a defect, there still may be a leakage current between those terminals.

### SUMMARY

The inventive concept provides an image sensor having an improved image quality by reducing a leakage current between a through via structure and an anti-reflection layer.

In addition, the issues to be solved by the technical idea of the inventive concept are not limited to those mentioned above, and other issues may be clearly understood by those of ordinary skill in the art from the following descriptions.

According to an aspect of the inventive concept, there is provided an image sensor including a semiconductor substrate including a first pixel, and a second pixel arranged adjacent to the first pixel, a pixel isolation structure between the first pixel and the second pixel, an anti-reflection layer arranged on the first pixel, the second pixel, and the pixel isolation structure, and a through via structure arranged in a through via hole that is in (e.g., penetrates) the anti-reflection layer and the semiconductor substrate, wherein the through via structure includes a first conductive layer arranged on an inner wall of the through via hole, and a second conductive layer arranged on the first conductive layer on the inner wall of the through via hole, and wherein the anti-reflection layer includes TiO₂, and the first conductive layer includes a material having a higher work function than Ti.

According to another aspect of the inventive concept, there is provided an image sensor including a semiconductor substrate including a first pixel and a second pixel arranged adjacent to the first pixel, a pixel isolation structure between the first pixel and the second pixel, an anti-reflection layer arranged on the first pixel, the second pixel, and the pixel isolation structure, a first front structure arranged on a first surface of the semiconductor substrate, and including a first conductive pattern, a second front structure contacting (e.g., being attached to) the first front structure, and including a second conductive pattern, and a through via structure which is arranged in a through via hole that is in (e.g., penetrates or extends through) the anti-reflection layer and the semiconductor substrate, the through via structure including a portion in the first front structure and a portion in the second front structure and electrically connecting the first conductive pattern to the second conductive pattern, wherein the through via structure includes a first conductive layer extending on an inner wall of the through via hole, and a second conductive layer extending on the first conductive layer on the inner wall of the through via hole, and the first conductive layer includes nitride, and the second conductive layer includes tungsten.

According to another aspect of the inventive concept, there is provided an image sensor including a first semiconductor chip including a first semiconductor substrate, on which logic elements are provided, and a first front structure on the first semiconductor substrate, a second semiconductor chip including a second semiconductor substrate stacked on the first semiconductor chip and including a plurality of pixels, an anti-reflection layer arranged on the second semiconductor substrate, and a second front structure under the second semiconductor substrate, and a through via structure that is in (e.g., penetrates) the anti-reflection layer, the second semiconductor substrate and the second front structure and electrically connects the logic elements to the plurality of pixels, wherein the anti-reflection layer includes TiO₂, the through via structure includes a second conductive layer including tungsten and a first conductive layer including a material having a higher work function than Ti, and wherein the first conductive layer contacts a side surface of the anti-reflection layer.

### BRIEF DESCRIPTION OF THE DRAWINGS

Embodiments will be more clearly understood from the following detailed description taken in conjunction with the accompanying drawings in which:

FIG. 1 illustrates an exploded perspective view of an image sensor of a stacked structure according to some embodiments;

FIGS. 2 and 3 are a circuit diagram of a unit pixel constituting pixels included in pixel regions of a second semiconductor chip in the image sensor of FIG. 1 and a schematic plan view corresponding thereto, respectively, according to some embodiments;

FIG. 4 is an enlarged plan view of portion A of the image sensor of the stacked structure of FIG. 1 according to some embodiments;

FIG. 5 is an enlarged cross-section view of portion A of the image sensor of the stacked structure of FIG. 1 according to some embodiments;

FIG. 6 is an enlarged cross-sectional view of portion A′ of the image sensor of FIG. 5 according to some embodiments;

FIGS. 7 and 8 are cross-sectional views of portion A′ of the image sensor of FIG. 5 according to some other embodiments;

FIGS. 9 through 12A illustrate a method of manufacturing an image sensor according to some embodiments;

FIG. 12B illustrates a structure of a through via structure in FIG. 12A according to some other embodiments;

FIG. 13 is an energy band diagram of an image sensor according to a comparative example;

FIG. 14 is a graph of a leakage current in an image sensor according to a comparative example;

FIG. 15 is an energy band diagram of an image sensor according to some embodiments;

FIG. 16 is a graph of a leakage current in an image sensor according to some embodiments;

FIG. 17 is a block diagram of an electronic device including a multi-camera module according to some embodiments;

FIG. 18 is a detailed block diagram of the camera module in FIG. 17 according to some embodiments; and

FIG. 19 is a block diagram of an image sensor according to some embodiments.

### DETAILED DESCRIPTION

Hereinafter, embodiments of the inventive concept will be described in detail with reference to the accompanying drawings. Identical reference numerals are used for the same constituent elements in the drawings, and duplicate descriptions thereof are omitted.

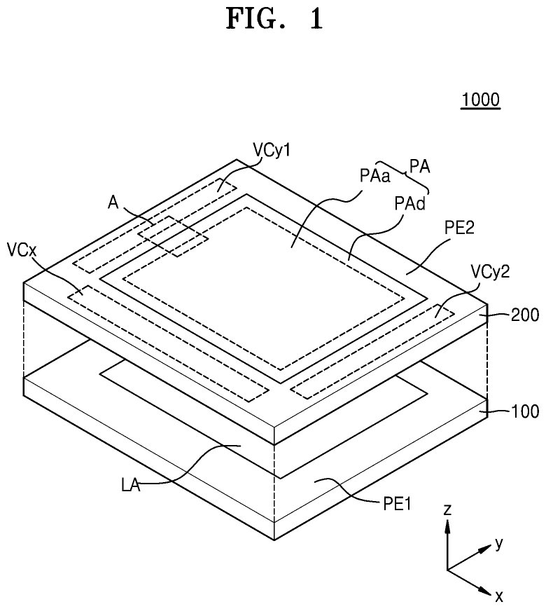

FIG. 1 illustrates an exploded perspective view of an image sensor of a stacked structure 1000 according to some embodiments, in which a first semiconductor chip 100 is isolated from a second semiconductor chip 200.

Referring to FIG. 1, the image sensor of the stacked structure (1000, hereinafter, “image sensor”) of the present embodiment may include the first semiconductor chip 100 and the second semiconductor chip 200. The image sensor 1000 according to the present embodiment may have a structure, in which the second semiconductor chip 200 is stacked on the first semiconductor chip 100. The image sensor 1000 of the present embodiment may include, for example, a complementary metal-oxide-semiconductor (CMOS) image sensor (CIS).

The first semiconductor chip 100 may include a logic region LA and a first periphery region PE1. The logic region LA may be arranged in the central region of the first semiconductor chip 100, and may include a plurality of logic elements arranged therein. The logic elements may include various elements for processing pixel signals from pixels in the second semiconductor chip 200. For example, logic elements may include analog signal processing elements, analog-to-digital converters (ADC), image signal processing elements, control elements, etc. However, elements included in the logic region LA are not limited thereto. For example, the logic region LA may include elements for supplying power or ground to pixels, or passive elements, such as resistors and capacitors.

The pixel signals from the pixel region PA of the second semiconductor chip 200 may be transmitted to the logic elements in the logic region LA of the first semiconductor chip 100. In addition, driving signals and power/ground signals may be transmitted from the logic elements of the logic region LA of the first semiconductor chip 100 to pixels in the pixel region PA of the second semiconductor chip 200.

The first periphery region PE1 may be arranged outside the logic region LA in a structure surrounding the logic region LA. For example, the first periphery region PE1 may be arranged outside the logic region LA in a shape surrounding four surfaces of the logic region LA. However, according to an embodiment, the first periphery region PE1 may be arranged only on the outside of two or three surfaces of the logic region LA. On the other hand, although not illustrated, through via regions may also be arranged in the first periphery region PE1, corresponding to the through via regions (VCx, VCy1, VCy2) of the second semiconductor chip 200.

The second semiconductor chip 200 may include a pixel region PA and a second periphery region PE2. The pixel region PA may be arranged in the central region of the second semiconductor chip 200, and a plurality of pixels PXa may be arranged in a two-dimensional array structure in the pixel region PA. The pixel region PA may include an active pixel region PAa and a dummy pixel region PAd surrounding the active pixel region PAa. Active pixels PXa may be arranged in the active pixel region PAa, and dummy pixels (not illustrated) may be arranged in a dummy pixel region PAd.

The second periphery region PE2 may be arranged outside the pixel region PA. For example, the second periphery region PE2 may have a structure of surrounding four surfaces of the pixel region PA, and may be arranged outside the pixel region PA. However, according to an embodiment, the second periphery region PE2 may be arranged only on the outside of two or three surfaces of the pixel region PA. The through via regions VCx, VCy1, and VCy2 may be arranged in the second periphery region PE2. A plurality of through via structures 230 may be arranged in the through via regions VCx, VCy1, and VCy2. The through via structure 230 may be connected to pixels of the pixel region PA via wirings of a second front structure 220 of the second semiconductor chip 200. In addition, the through via structure 230 may connect the wirings of the second front structure 220 of the second semiconductor chip 200 to the wirings of the first front structure 120 of the first semiconductor chip 100. The wirings of the first front structure 120 of the first semiconductor chip 100 may be connected to logic elements of the logic region LA.

The through via regions VCx, VCy1, and VCy2 may include a row through via region VCx extending in a first direction (x direction), and column through via regions VCy1 and VCy2 extending in a second direction (y direction). The column through via regions VCy1 and VCy2 may include a first column through via region VCy1 on the left side and a second column through via region VCy2 on the right side of the pixel region PA. According to an embodiment, any one of the first column through via region VCy1 and the second column through via region VCy2 may be omitted.

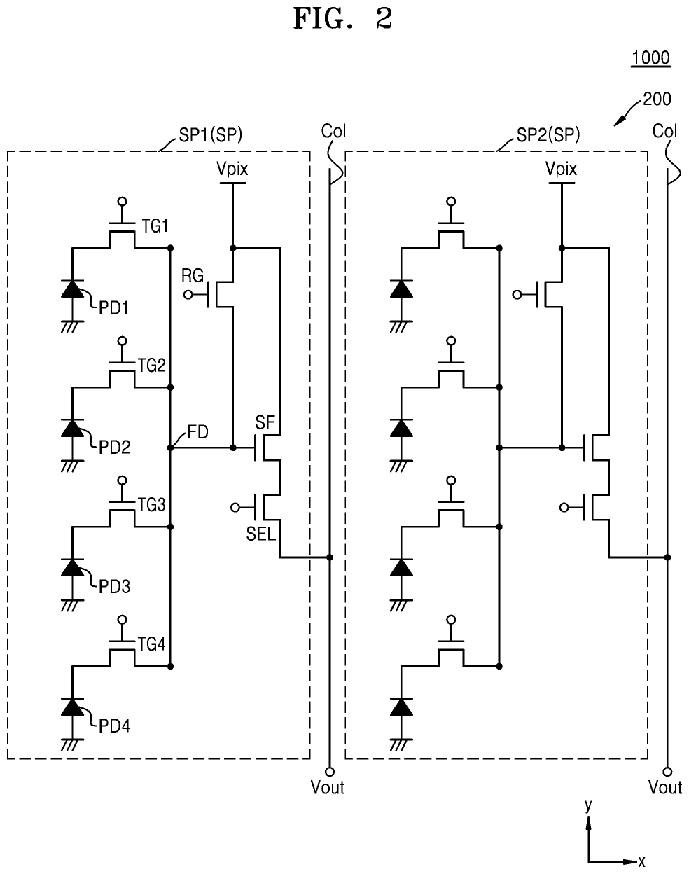

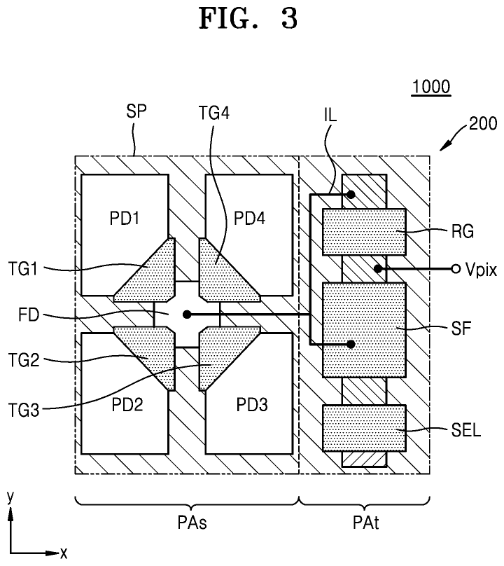

FIGS. 2 and 3 are a circuit diagram of a unit pixel constituting pixels included in pixel regions of the second semiconductor chip 100 in the image sensor of FIG. 1, and a schematic plan view corresponding thereto, respectively, according to some embodiments. Hereinafter, FIGS. 2 and 3 are described with reference to FIG. 1 together.

Referring to FIGS. 1, 2, and 3, in the image sensor 1000 of the present embodiment, a plurality of shared pixels SP may be arranged in a two-dimensional array structure in the active pixel region PAa of the second semiconductor chip 200. Although two shared pixels SP1 and SP2 are illustrated in FIG. 2, the plurality of shared pixels SP may be arranged in a two-dimensional array structure in the image sensor 1000, and the plurality of shared pixels SP may be arranged in the first direction (x direction) and the second direction (y direction) in the active pixel region PAa of the second semiconductor chip 200.

Each of the shared pixels SP may include a pixel sharing region PAs and a transistor (TR) region PAt. For example, a photodiode PD, a transmission TR TG, and a floating diffusion region FD may be arranged in the pixel sharing region PAs, and a reset TR RG, a source follower TR SF, and a selection TR SEL may be arranged in the TR region PAt.

The photodiode PD, as a P-N junction diode, may generate a charge, for example, electrons, which are negative charges, and holes, which are positive charges, in proportion to the amount of incident light. The transmission TR TG may transmit the charge generated by the photodiode PD to the floating diffusion region FD, and the reset TR RG may periodically reset the charge stored in the floating diffusion region FD. In addition, the source follower TR SF, as a buffer amplifier, may buffer a signal according to the charge charged or stored in the floating diffusion region FD, and the selection TR SEL, as a TR acting as a switch, may select the corresponding pixel. On the other hand, a column line Col may be connected to the source region of the selection TR SEL, and the voltage of the source region of the selection TR SEL may be output as an output voltage Vout via the column line Col. In the image sensor 1000 of the present embodiment, one photodiode PD may correspond to one pixel, and accordingly, hereinafter, unless particularly specified, the photodiode PD and the pixel may be treated as having the same concept.

As illustrated in FIG. 3, four photodiodes PD may be arranged in one pixel sharing region PAs. Accordingly, one shared pixel SP may include four pixels, for example, four active pixels PXa. The shared pixel SP may have a structure, in which four photodiodes (PD1 through PD4) surround and share one floating diffusion region FD.

In one shared pixel SP, sharing one floating diffusion region FD by the four photodiodes (PD1 through PD4), as understood from the circuit diagram of FIG. 2, may be performed by using first through fourth transmission TRs TG1 through TG4 respectively corresponding to first through fourth photodiodes PD1 through PD4. The first transmission TR TG1 corresponding to the first photodiode PD1, the second transmission TR TG2 corresponding to the second photodiode PD2, the third transmission TR TG3 corresponding to the third photodiode PD3, and the fourth transmission TR TG4 corresponding to the fourth photodiode PD4 may share the floating diffusion region FD as a common drain region.

On the other hand, the concept of sharing the shared pixel SP may include not only that the four of the first through fourth photodiodes PD1 through PD4 share one floating diffusion region FD but that the four of the first through fourth photodiodes PD1 through PD4 share the pixel TRs (RG, FS, and SEL) except for the first through fourth transmission TRs TG1 through TG4. In other words, the four of the first through fourth photodiodes PD1 through PD4 constituting the shared pixel SP may share the reset TR RG, the source follower TR SF, and the selection TR SEL. The reset TR RG, the source follower TR SF, and the selection TR SEL may be arranged in the second direction (y direction) in the TR region PAt. However, the reset TR RG, the source follower TR SF, and the selection TR SEL may be arranged in the first direction (x direction) in the TR region PAt, according to the arrangement structure of the first through fourth photodiodes PD1 through PD4 and the first through fourth transmission TRs TG1 through TG4 in the pixel sharing region PAs.

Referring to the circuit diagram of FIG. 2, the connection relationship between the pixel TRs (TG, RG, SF, and SEL) may be simply understood that the four of the first through fourth photodiodes PD1 through PD4 constitute source regions of the four of the first through fourth transmission TRs TG1 through TG4 respectively corresponding thereto. The floating diffusion region FD may constitute a drain region (e.g., a common drain region) of the first through fourth transmission TRs TG1 through TG4, and may be connected to a source region of the reset TR RG via a wiring IL. In addition, the floating diffusion region FD may also be connected to a gate electrode of the source follower TR SF via the wiring IL. A drain region of the reset TR RG and a drain region of the source follower TR SF may be shared and be connected to a power voltage Vpix. A source region of the source follower TR SF and a drain region of the selection TR SEL may be shared with each other. The output voltage Vout may be connected to the source region of the selection TR SEL. In other words, a voltage of the source region of the selection TR SEL may be output as the output voltage Vout via a column line Col.

In the image sensor 1000 of the present embodiment, a unit-shared pixel SP may include four pixels in the pixel sharing region PAs and TRs (RG, SF, and SEL) of the TR region PAt corresponding thereto, and in addition, the first through fourth transmission TRs TG1 through TG4 corresponding to the number of the shared first through fourth photodiodes PD1 through PD4 may be arranged in the pixel sharing region PAs. On the other hand, although a structure, in which four pixels constitute one shared pixel SP has been described, a shared pixel structure of the image sensor 1000 of the present embodiment is not limited thereto. For example, in the image sensor 1000 of the present embodiment, two pixels may constitute one shared pixel, or eight pixels may constitute one shared pixel. In addition, according to an embodiment, single pixels, not the shared pixels, may also be arranged in the active pixel region PAa. In the case that the single pixels are in the active pixel region PAa, each pixel may include the photodiode PD, the floating diffusion region FD, and pixel TRs (TG, RG, SF, and SEL).

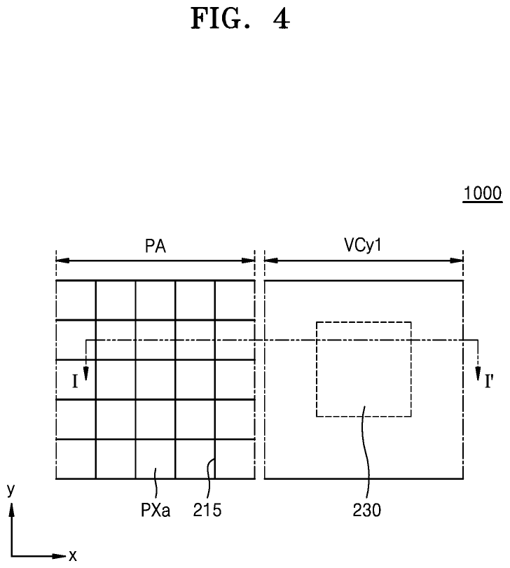

FIG. 4 is an enlarged plan view of portion A of the image sensor 1000 of the stacked structure of FIG. 1 according to some embodiments.

Referring to FIGS. 1 and 4, the pixel region PA may include the active pixel region PAa. The active pixels PXa may be arranged in a two-dimensional array structure in the active pixel region PAa. The active pixels PXa of the active pixel region PAa may be isolated from each other by a pixel isolation structure 215. As understood from FIG. 4, the pixel isolation structure 215 may have a two-dimensional grating shape corresponding to the two-dimensional array structure of the active pixels PXa, in a plan view.

The first column through via region VCy1 may include a plurality of through via structures 230. In some embodiments, the through via structure 230 may electrically connect the first semiconductor chip 100 to the second semiconductor chip 200. In some embodiments, the through via structure 230 may electrically connect the active pixel region PAa to the logic region LA.

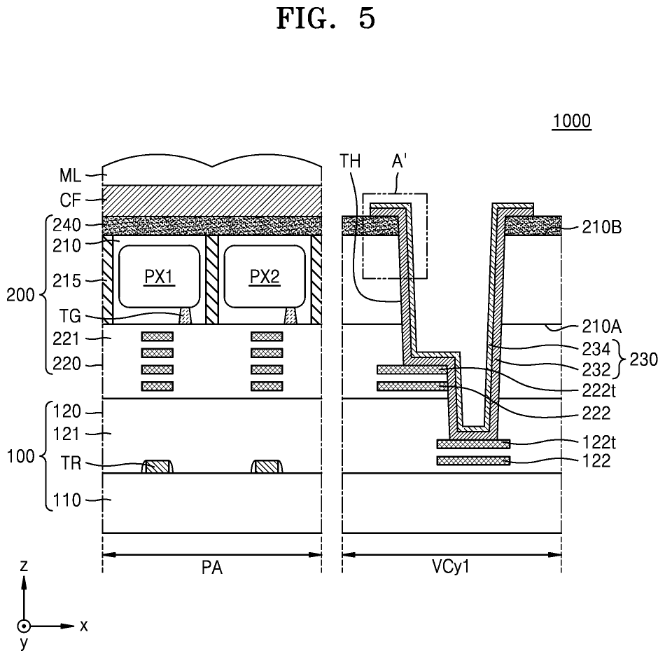

FIG. 5 is a cross-sectional view taken along line I-I′ in FIG. 4 according to some embodiments.

Referring to FIG. 5, the image sensor 1000 may include micro lenses ML, a color filter CF, the first semiconductor chip 100, the second semiconductor chip 200, and the through via structure 230.

The color filters CF and the microlenses ML may be formed on an upper portion of the second semiconductor chip 200. A structure, in which color filters CF and microlenses ML are formed in a direction opposite to the second front structure 220, based on a second semiconductor substrate 210, in which the pixels PX are formed, in the second semiconductor chip 200, as a reference, may be referred to as a back side illumination (BSI) structure, and in the image sensor 1000 of the present embodiment, the second semiconductor chip 200 may have a BSI structure.

The first semiconductor chip 100 may include a first semiconductor substrate 110 and the first front structure 120. When viewed in a vertical structure in a third direction (z direction), the first semiconductor substrate 110 may be at a lower portion the first semiconductor chip 100, and the first front structure 120 may be at an upper portion of the first semiconductor chip 100.

The first semiconductor chip 100 may further include a memory region. Memory elements may be arranged in the memory region. For example, the memory elements may include dynamic random access memory (DRAM) and/or magnetic RAM (MRAM). Accordingly, in the memory region, a plurality of DRAM cells and/or a plurality of MRAM cells may be arranged in a two-dimensional array structure. On the other hand, when the first semiconductor chip 100 includes a memory region, memory elements of the memory region may be formed together with logic elements of the logic region. For example, logic elements of the logic region and memory elements of the memory region may be formed together by using a CMOS process. For reference, the memory elements in the memory region may be used as an image buffer memory for storing a frame image.

The first semiconductor substrate 110 may be arranged under the first front structure 120. Logic elements may be formed on the first semiconductor substrate 110. The first semiconductor substrate 110 may include silicon. However, the material of the first semiconductor substrate 110 is not limited to silicon. For example, the second semiconductor substrate 210 may include a single-component semiconductor, such as germanium (Ge), or a compound semiconductor, such as a silicon carbide (SiC), gallium arsenide (GaAs), indium arsenide (InAs), and indium phosphide (InP).

The first front structure 120 may include an electronic element TR, a first insulating layer 121, and a first conductive pattern 122. In the first column through via region VCy1 in FIG. 5, although two layers of the first conductive pattern 122 are illustrated for convenience, a plurality of layers of the first conductive pattern 122 may be arranged, in the first front structure 120.

The electronic element TR may include a gate insulating layer, a gate electrode, and a spacer. The gate electrode may include at least one of doped polysilicon, a metal, metal silicide, metal nitride, or a metal-included layer. In some embodiments, a first pixel PX1 and a second pixel PX2 of the second semiconductor chip 200 may be electrically connected to the electronic element TR. The electronic element TR may be, for example, a transistor.

The first conductive pattern 122 may be connected to logic elements of a logic region (for example, the logic region LA in FIG. 1). In addition, the first conductive pattern 122 of the first front structure 120 may be connected to a second conductive pattern 222 of the second front structure 220 via the through via structure 230.

The second semiconductor chip 200 may include the second semiconductor substrate 210, the second front structure 220, and an anti-reflection structure 240. When viewed in a vertical structure in a third direction (z direction), the second semiconductor substrate 210 may be at an upper portion the second semiconductor chip 200, and the second front structure 220 may be at a lower portion of the second semiconductor chip 200.

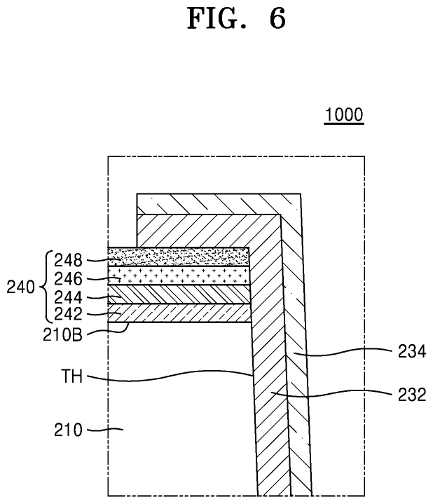

The second semiconductor substrate 210 may include the first pixel PX1, the second pixel PX2, and the pixel isolation structure 215. The second semiconductor substrate 210 may include a first surface 210A and a second surface 210B opposite to the first surface 210A. The first surface 210A of the second semiconductor substrate 210 may include a lower surface of the second semiconductor substrate 210 in contact with the second front structure 220. The second surface 210B of the second semiconductor substrate 210 may include an upper surface of the second semiconductor substrate 210 in contact with the anti-reflection structure 240. The second semiconductor substrate 210 may include silicon. However, the material of the second semiconductor substrate 210 is not limited to silicon. The material of the second semiconductor substrate 210 may be the same as the material of the first semiconductor substrate 110. The anti-reflection structure 240 is described below with reference to FIG. 6.

The pixel isolation structure 215 may have a structure penetrating the second semiconductor substrate 210 in the third direction (z direction). As the pixel isolation structure 215 is formed in a structure penetrating the second semiconductor substrate 210, cross-talk due to obliquely incident light may be reduced or prevented.

The second front structure 220 may include a second insulating layer 221 and the second conductive pattern 222. In the first column through via region VCy1 in FIG. 5, although two layers of the second conductive pattern 222 are illustrated for convenience, a plurality of layers of the second conductive pattern 222 may be arranged, in the second front structure 220. The second conductive patterns 222 of different layers may be connected to each other via vertical contacts. The second conductive pattern 222 may be connected to the pixels (PX1, PX2).

Referring to FIGS. 1 and 5, the through via structure 230 may include a first conductive layer 232 and a second conductive layer 234. The first conductive layer 232 may be arranged on an inner wall of a through via hole TH. The first conductive layer 232 may be in contact with a side surface of the anti-reflection structure 240. The first conductive layer 232 may extend along an inner surface of the through via hole TH.

In some embodiments, the first conductive layer 232 may include nitride. In some embodiments, the first conductive layer 232 may include metal nitride including at least one metal of W, Ti, and Ta. For example, the first conductive layer 232 may include metal nitride including W, Ti and/or Ta. The first conductive layer 232 may include at least one of WN, TiN, and TaN. For example, the first conductive layer 232 may include WN, TiN, and/or TaN. In some embodiments, the first conductive layer 232 may not include (i.e., may be free of) Ti. The first conductive layer 232 may include a barrier layer with respect to the second conductive layer 234. In some embodiments, a work function of the material forming the first conductive layer 232 may be greater than the work function of Ti. In some embodiments, the work function of the material forming the first conductive layer 232 may be greater than 4.33 eV.

The second conductive layer 234 may be arranged on the first conductive layer 232 on the inner wall of the through via hole TH. The second conductive layer 234 may contact the first conductive layer 232. The second conductive layer 234 may be spaced apart from the side surface of the anti-reflection structure 240. In other words, the second conductive layer 234 may not contact the anti-reflection structure 240. The second conductive layer 234 may include W (tungsten). In some embodiments, the first conductive layer 232 may extend between the second conductive layer 234 and the inner surface of the through via hole TH and may separate the second conductive layer 234 from the inner surface of the through via hole TH.

The through via structure 230 may be arranged in the through via regions (VCx, VCy1, and VCy2). The through via structure 230 may be formed in the through via hole TH penetrating the second semiconductor substrate 210, the second front structure 220, and a portion of the first front structure 120.

The first front structure 120 and the second front structure 220 may include the first conductive pattern 122 and the second conductive pattern 222, respectively, and the first conductive pattern 122 and the second conductive pattern 222 may function as an etching stop layer in the etching process for forming the through via hole TH. For example, an uppermost second wiring 222t among the second conductive patterns 222 of the second front structure 220 may function as an etching stop layer. The uppermost first wiring 122t of the first conductive pattern 122 of the first front structure 120 may function as an etching stop layer. The first conductive layer 232 may contact the first conductive pattern 122 and the second conductive pattern 222.

In some embodiments, based on the locations and structures of the anti-reflection structure 240 and the second wiring 222t, the through via hole TH may have a large width from the location of the anti-reflection structure 240 to the location of the second wiring 222t. In some embodiments, the through via hole TH may have a narrow width from the location of the second wiring 222t to the location of a first wiring 122t. The through via hole TH and the through via structure 230 may have tapered shapes. In some embodiments, an upper portion of the through via structure 230, which is located above the second wiring 222t, may have a width wider than a width of a lower portion of the through via structure 230, which is located below the second wiring 222t, as illustrated in FIG. 5. Further, each of the upper portion and the lower portion of the through via structure 230 may have a width decreasing with an increasing depth of the through via hole TH, as illustrated in FIG. 5.

The second wiring 222t and the first wiring 122t may correspond to a power application wiring or a signal application wiring, and may contact the through via structure 230. In some embodiments, power, for example, a negative (−) voltage from the first semiconductor chip 100 may applied to pixels PX of the pixel region PA of the second semiconductor chip 200 via the first wiring 122t, the through via structure 230, and the second wiring 222t.

In addition, the negative (−) voltage from the first semiconductor chip 100 may be applied to the pixel isolation structure 215 of the second semiconductor chip 200 via the first wiring 122t and the through via structure 230. In this case, an inner space portion of the through via hole TH may be filled with a passivation layer, such as a solder resist before a color filter is formed down the line.

In some embodiments, the through via structure 230 may extend from the side surface of the anti-reflection structure 240 onto the second surface 210B of the second semiconductor substrate 210. In some embodiments, the through via structure 230 may extend from the second surface 210B to the first surface 210A of the second semiconductor substrate 210. In some embodiments, the through via structure 230 may extend from the second front structure 220 to a portion of the first front structure 120.

Accordingly, as described above, the negative (−) voltage from the first semiconductor chip 100 may be applied to the pixel isolation structure 215 via the first wiring 122t and the through via structure 230. In addition, the through via structure 230 may actually extend onto the anti-reflection structure 240 on the upper surface of the second semiconductor substrate 210.

The anti-reflection structure 240 may include a transparent insulating layer of an oxide layer type. The anti-reflection structure 240 may be formed in a multilayer shape. For example, the anti-reflection structure 240 may include an anti-reflection layer, a lower insulation layer under the antireflection layer, and an upper insulation layer on the anti-reflection layer. On the other hand, the through via structure 230 may extend up to a certain portion on the anti-reflection structure 240. For example, the through via structure 230 may not be connected to another through via structure 230 which is adjacent thereto.

In addition, the image sensor 1000 of the present embodiment may be utilized not only in cameras, optical inspection devices, or the like including image sensors, but in fingerprint sensors, iris sensors, vision sensors, etc. Furthermore, the technical idea of the image sensor 1000 of the present embodiment may be extended and utilized in a package-type semiconductor device to which a negative (−) bias voltage is applied, beyond the field of the image sensor.

In the image sensor 1000, TiO₂ may be selected instead of HfO₂ as a material constituting the anti-reflection structure 240, and any one of TiN, WN, and TaN may be selected as a material constituting the through via structure 230. For example, the through via structure 230 may include TiN, WN and/or TaN. In some embodiments, the through via structure 230 may not include (i.e., may be free of) Ti. The through via structure 230 may include materials having a higher work function than Ti. In some embodiments, the side surface of the anti-reflection structure 240 may contact the through via structure 230, and by using a TiN—TiO₂—TiN junction, a leakage current flowing to the anti-reflection structure 240 may be suppressed. In addition, by selecting TiO₂ instead of HfO₂ as the material constituting the anti-reflection structure 240, the image sensor 1000 may improve sensitivity with respect to blue color light. By using this structure, the reliability of the image sensor 1000 may be improved.

FIG. 6 is an enlarged cross-sectional view of portion A′ of the image sensor 1000 of FIG. 5 according to some embodiments.

Referring to FIG. 6 together with FIG. 5, the anti-reflection structure 240 may include a first dark current suppression layer 242, an anti-reflection layer 244, an insulating layer 246, and a second dark current suppression layer 248. The anti-reflection structure 240 may be formed by stacking, on the second surface 210B of the second semiconductor substrate 210, the first dark current suppression layer 242, the anti-reflection layer 244, the insulation layer 246, and the second dark current suppression layer 248 in sequence.

The first dark current suppression layer 242 may be arranged on the second semiconductor substrate 210. A lower surface of the first dark current suppression layer 242 may be in contact with the second surface 210B of the second semiconductor substrate 210. An upper surface of the first dark current suppression layer 242 may be in contact with a lower surface of the anti-reflection layer 244. In addition, the first dark current suppression layer 242 may be arranged between the anti-reflection layer 244 and the first semiconductor substrate 110.

In some embodiments, a side surface of the first dark current suppression layer 242 may be exposed by the through via hole TH. In some embodiments, the side surface of the first dark current suppression layer 242 may be in contact with the first conductive layer 232 of the through via structure 230. In some embodiments, the side surface of the first dark current suppression layer 242 may be spaced apart from the second conductive layer 234 of the through via structure 230.

In some embodiments, the first dark current suppression layer 242 may include at least one material of aluminum oxide (AlO), tantalum oxide (TaO), hafnium oxide (HfO), zirconium oxide (ZrO), and lanthanum oxide (LaO). In some embodiments, the first dark current suppression layer 242 may include aluminum oxide (AlOₓ, x is greater than 0 and is less than or equal to about 2). In some embodiments, the first dark current suppression layer 242 may include a single material layer including aluminum oxide AlOₓ.

The anti-reflection layer 244 may be arranged on the first dark current suppression layer 242. In some embodiments, a side surface of the anti-reflection layer 244 may be exposed by the through via hole TH. In some embodiments, the side surface of the anti-reflection layer 244 may contact the first conductive layer 232 of the through via structure 230. In some embodiments, the side surface of the anti-reflection layer 244 may be spaced apart from the second conductive layer 234 of the through via structure 230. In some embodiments, the anti-reflection layer 244 may include titanium oxide TiO₂. The anti-reflection layer 244 may include a single layer including TiO₂.

The insulating layer 246 may be arranged on the anti-reflection layer 244. In some embodiments, a side surface of the insulating layer 246 may be exposed by the through via hole TH. In some embodiments, the side surface of the insulating layer 246 may be in contact with the first conductive layer 232 of the through via structure 230. In some embodiments, the side surface of the insulating layer 246 may be spaced apart from the second conductive layer 234 of the through via structure 230. In some embodiments, the insulating layer 246 may include at least one material of PETEOS, SiOC, silicon oxide (SiO_{y}, y is greater than 0 and is less than or equal to about 2), and SiN. The insulating layer 246 may include a single material layer including SiO₂.

The second dark current suppression layer 248 may be arranged on the insulating layer 246. In some embodiments, a side surface of the second dark current suppression layer 248 may be exposed by the through via hole TH. In some embodiments, the side surface of the second dark current suppression layer 248 may be in contact with the first conductive layer 232 of the through via structure 230. In some embodiments, the side surface of the second dark current suppression layer 248 may be spaced apart from the second conductive layer 234 of the through via structure 230.

The second dark current suppression layer 248 may include at least one material of AlO, TaO, HfO, ZrO, and LaO. In some embodiments, the second dark current suppression layer 248 may include a single material layer including HfO. In other embodiments, the first dark current suppression layer 242 and the second dark current suppression layer 248 may include the same material. Each of the first dark current suppression layer 242 and the second dark current suppression layer 248 may include at least one of aluminum oxide (AlOₓ, x is greater than 0 and is less than or equal to about 2) and hafnium oxide (HfO). For example, each of the first dark current suppression layer 242 and the second dark current suppression layer 248 may include aluminum oxide and/or hafnium oxide. In some embodiments, the first dark current suppression layer 242 and the second dark current suppression layer 248 may not include (i.e., may be free of) HfO₂. In addition, the anti-reflection structure 240 may not include (i.e., may be free of) HfO₂.

According to the image sensor 1000 described with reference to FIGS. 5 and 6, the reduction in sensing blue color light thereof may be improved as the anti-reflection layer 244 includes titanium oxide. In addition, because the work function of the first conductive layer 232 is relatively high, even though the first conductive layer 232 contacts the anti-reflection layer 244, a leakage current of the image sensor 1000 may be reduced.

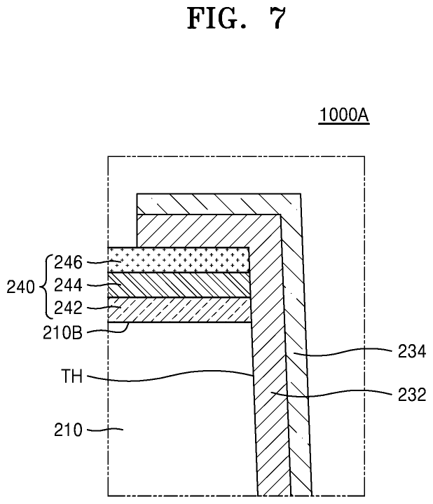

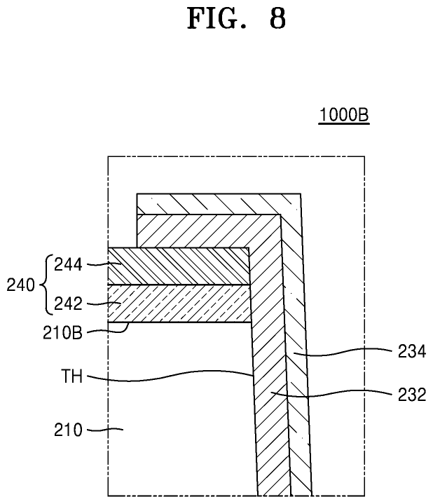

FIGS. 7 and 8 are cross-sectional views of portion A′ of the image sensor of FIG. 5 according to some other embodiments. Differences with respect to FIG. 6 are mainly described.

Referring to FIG. 7, in the image sensor 1000A according to some embodiments, the anti-reflection structure 240 may include multilayers including the first dark current suppression layer 242, the anti-reflection layer 244, and the insulating layer 246. In other words, the anti-reflection structure 240 may not include the second dark current suppression layer 248, and the uppermost layer of the anti-reflection structure 240 may be the insulating layer 246. A portion of an upper surface of the insulating layer 246 may be in direct contact with the first conductive layer 232 of the through via structure 230.

Referring to FIG. 8, in the image sensor 1000B according to some embodiments, the anti-reflection structure 240 may include multilayers including the first dark current suppression layer 242 and the anti-reflection layer 244. In other words, the anti-reflection structure 240 may not include the second dark current suppression layer 248 and the insulating layer 246. A portion of an upper surface of the anti-reflection layer 244 may be in direct contact with the first conductive layer 232 of the through via structure 230.

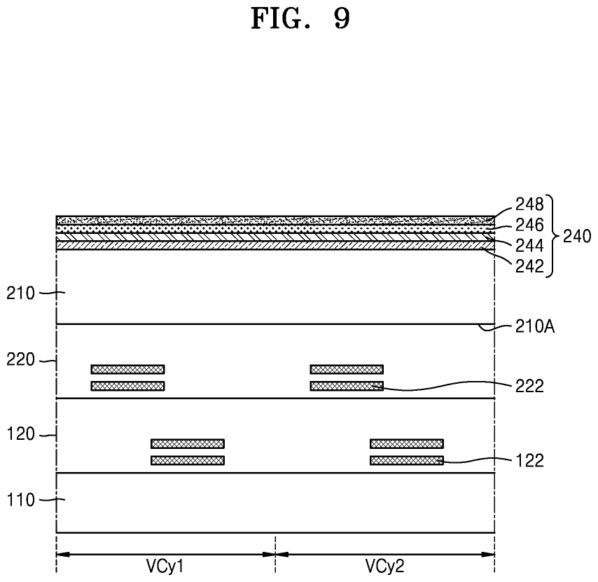

FIGS. 9 through 12A illustrate a method of manufacturing an image sensor according to some embodiments.

Referring to FIG. 9, firstly, a semiconductor element, in which the first front structure 120 of the first semiconductor chip 100 and the second front structure 220 of the second semiconductor chip 200 are bonded to face each other, may be provided. In this case, the first front structure 120 may include the first conductive pattern 122, and the second front structure 220 may include the second conductive pattern 222. The first front structure 120 may contact the second front structure 220. In some embodiments, an adhesive layer (not illustrated) may be formed between the first front structure 120 and the second front structure 220.

Next, the anti-reflection structure 240 may be formed on the second front structure 220 of the second semiconductor chip 200. The first dark current suppression layer 242, the anti-reflection layer 244, the insulating layer 246, and the second dark current suppression layer 248 may be sequentially stacked. In this case, the anti-reflection layer 244 may include a single layer including TiO₂.

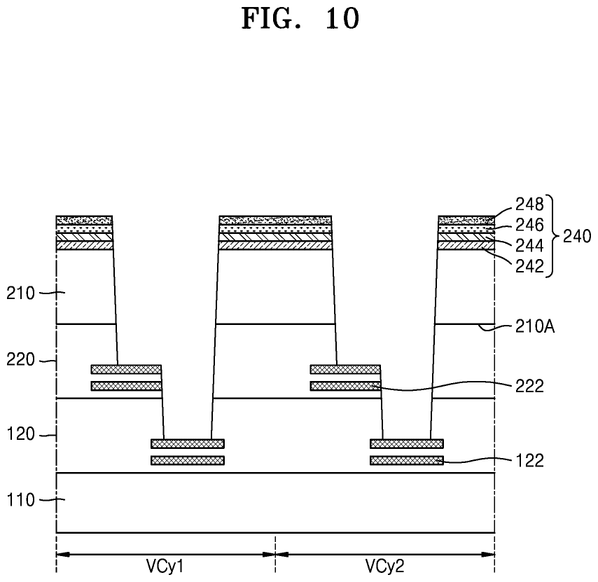

Referring to FIG. 10, an etching mask pattern (not illustrated) may be formed on the second dark current suppression layer 248. The etching mask pattern may include a mask for forming the through via hole TH. By etching the anti-reflection structure 240, the second semiconductor chip 200, and the first front structure 120 by using the etching mask pattern, the through via hole TH exposing the first conductive pattern 122 of the first front structure 120 and the second conductive pattern 222 of the second front structure 220 may be formed.

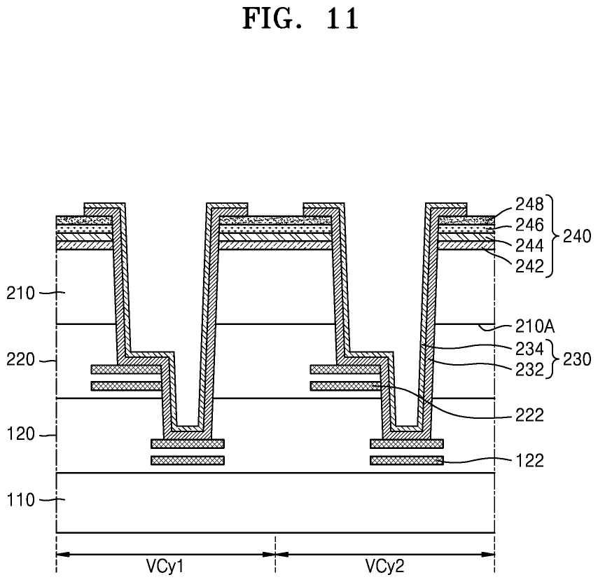

Referring to FIG. 11, a through via structure 230 covering an inner wall of the through via hole TH may be formed. The through via structure 230 may cover an upper surface of the second dark current suppression layer 248 (e.g., a portion of the upper surface of the second dark current suppression layer 248). The method of forming the through via structure 230 may firstly include forming the first conductive layer 232 on the inner wall of the through via hole TH and the upper surface of the second dark current suppression layer 248, and forming the second conductive layer 234 on the upper surface of the first conductive layer 232. Next, a portion of the second dark current suppression layer 248 may be exposed by etching a portion of the through via structure 230 on the second dark current suppression layer 248.

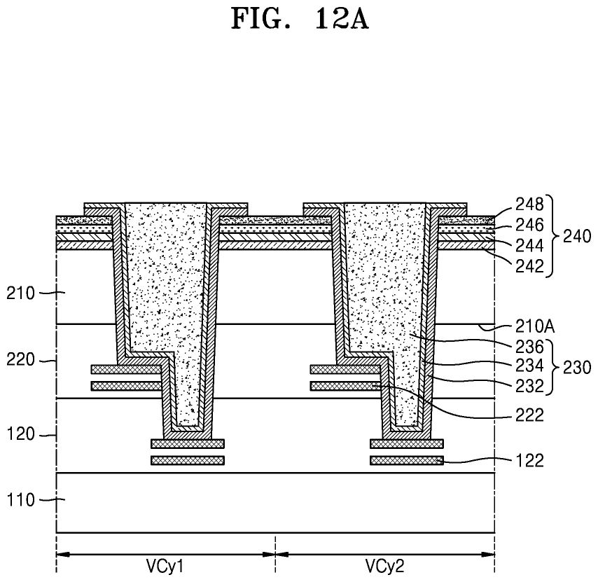

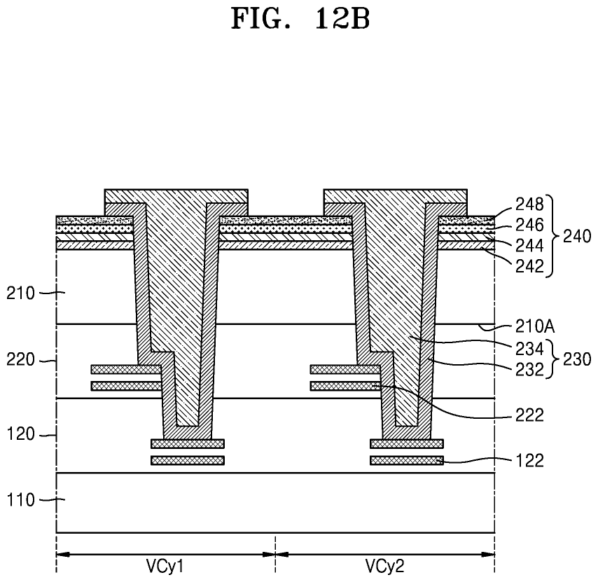

Referring to FIG. 12A, a passivation layer 236 including a solder resist PR may be formed in an inner space of the second conductive layer 234 of the through via structure 230. In this case, the passivation layer 236 may be formed before the color filter CF is formed.

FIG. 12B illustrates a structure of the through via structure 230 in FIG. 12A according to some other embodiments.

Referring to FIG. 12B, the width of the through via hole TH may be less than the width of the through via hole TH in FIG. 12A. In the subsequent operation, the thicknesses of the first conductive layer 232 and the second conductive layer 234 may be formed to be greater than those of the first conductive layer 232 and the second conductive layer 234 in FIG. 12A. The first conductive layer 232 may be formed along an inner wall of the through via hole TH and an upper surface of the second dark current suppression layer 248 in advance, and the second conductive layer 234 may be formed while completely filling the inner space of the first conductive layer 232. Unlike as illustrated in FIG. 12A, the through via structure 230 in FIG. 12B may not include the passivation layer 236 illustrated in FIG. 12A.

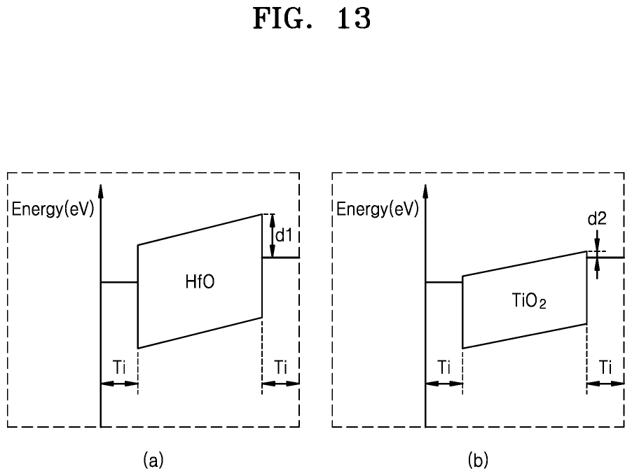

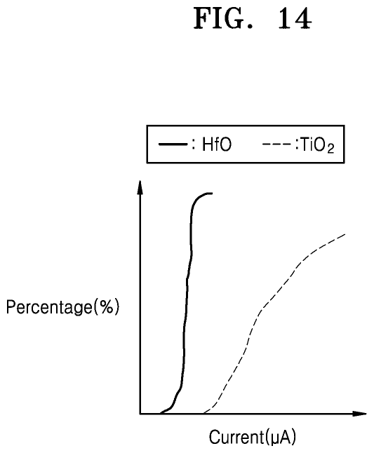

FIG. 13 is an energy band diagram of an image sensor according to a comparative example. FIG. 14 is a graph of a leakage current in an image sensor, according to a comparative example.
(a) of FIG. 13 is an energy band diagram when Ti—HfO—Ti is bonded. (b) of FIG. 13 is an energy band diagram when Ti—TiO₂—Ti is bonded. In (a) and (b) of FIG. 13, the vertical axis of the energy band diagram may represent energy, and the horizontal axis may represent bonded materials. In the graph of FIG. 14, the horizontal axis may represent a leakage current, and the vertical axis may represent a probability distribution. The unit of the horizontal axis may represent micro-amperes (μA), and the unit of the vertical axis may represent percent (%) in FIG. 14.

Referring to (a) of FIG. 13, the vertical axis of the energy band diagram may represent energy, and the horizontal axis may represent bonded materials. The unit of the vertical axis may be eV. In this case, in the energy band diagram, Ti has been used as the material of the first conductive layer 232, and HfO has been used as the material of the anti-reflection layer 244. The work function of Ti may be 4.33 eV, and the electron affinity of HfO may be 2.65 eV. When Ti and HfO are bonded, the energy barrier d1 has been 1.68 eV. Due to the relatively high energy barrier d1, the leakage current between the first conductive layer 232 and the anti-reflection layer 244 may have been suppressed. However, because HfO is used as the anti-reflection layer 244, there may be an issue that the sensitivity to the blue color light is reduced.

Referring to (b) of FIG. 13, to solve the sensitivity to the blue color light, Ti has been used as the material of the first conductive layer 232, and TiO₂ has been used as the material of the anti-reflection layer 244. The sensitivity to the blue color light has been improved, but as illustrated in the energy band diagram, an energy barrier d2 has been relatively low, and the energy barrier d2 has been 0.18 eV. As a result, there has been an issue that a leakage current occurs between the anti-reflection layer 244 and the first conductive layer 232.

Referring to FIG. 14, the solid line may represent the case, in which the anti-reflection layer 244 includes HfO with respect to the first conductive layer 232 including Ti, and the dotted line may represent the case in which the anti-reflection layer 244 includes TiO₂ with respect to the first conductive layer 232 including Ti. Because the dotted line is biased to the right side than the solid line, it may be understood that the leakage current between the anti-reflection layer 244 and the first conductive layer 232 is relatively increased in the Ti—TiO₂—Ti junction compared to the actual Ti—HfO—Ti junction.

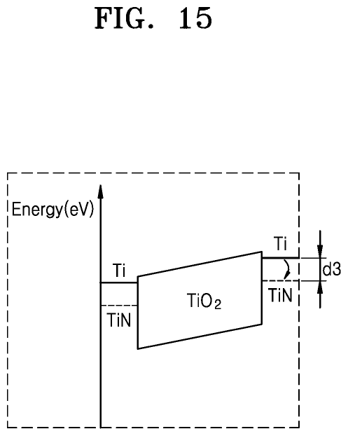

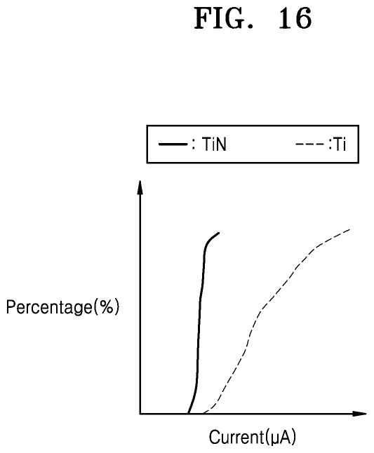

FIG. 15 is an energy band diagram of an image sensor according to some embodiments. FIG. 16 is a graph of a leakage current in an image sensor according to some embodiments.

FIG. 15 is an energy band diagram comparing the case, in which Ti—TiO₂—Ti is bonded, with the case in which TiN—TiO₂—TiN is bonded. In the graph of FIG. 16, the horizontal axis may represent a leakage current, and the vertical axis may represent a probability distribution. The unit of the horizontal axis may represent micro-amperes (μA), and the unit of the vertical axis may represent percent (%) in FIG. 16.

Referring to FIG. 15, when TiO₂ is used for the anti-reflection layer 244, and TiN, rather than Ti, is used for the first conductive layer 232, an energy barrier d3 may be increased. The energy barrier d3 is 0.35 eV at an interface between the anti-reflection layer 244 and the first conductive layer 232, which is higher than the energy barrier d2 illustrated in (b) of FIG. 13.

Referring to FIG. 16, in the case, in which TiO₂ is used for the anti-reflection layer 244, the solid line may represent the case, in which TiN is used for the first conductive layer 232, and the dotted line may represent the case, in which Ti is used for the first conductive layer. Because the dotted line moves and is biased to the right side of the solid line, the leakage current may be reduced when the first conductive layer includes TiN, rather than Ti.

Thus, according to an embodiment, when the anti-reflection layer 244 includes TiO₂, and the first conductive layer includes TiN, the sensitivity of the image sensor 1000 to the blue color light may be improved and the leakage current thereof may be suppressed.

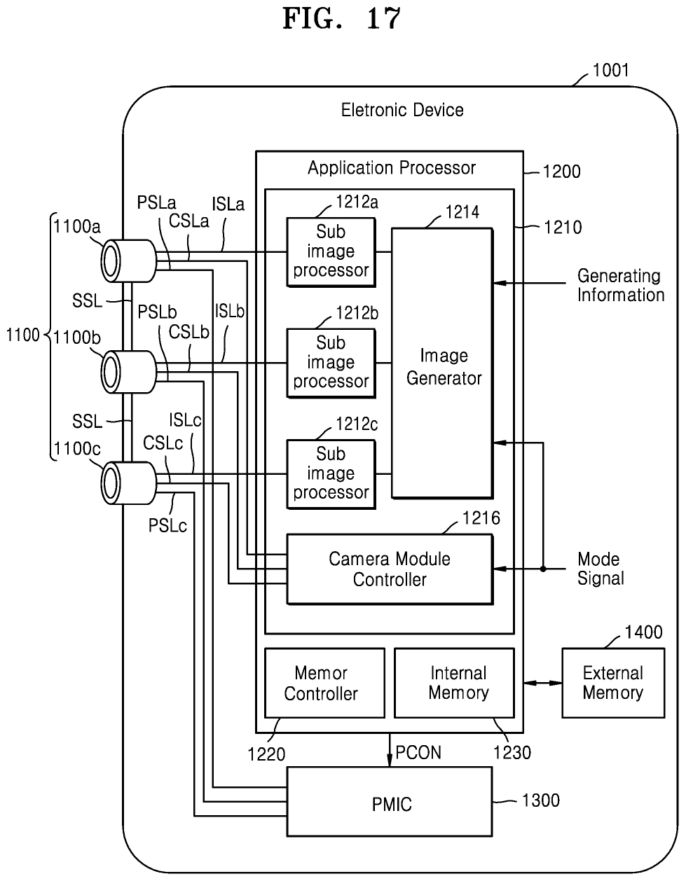

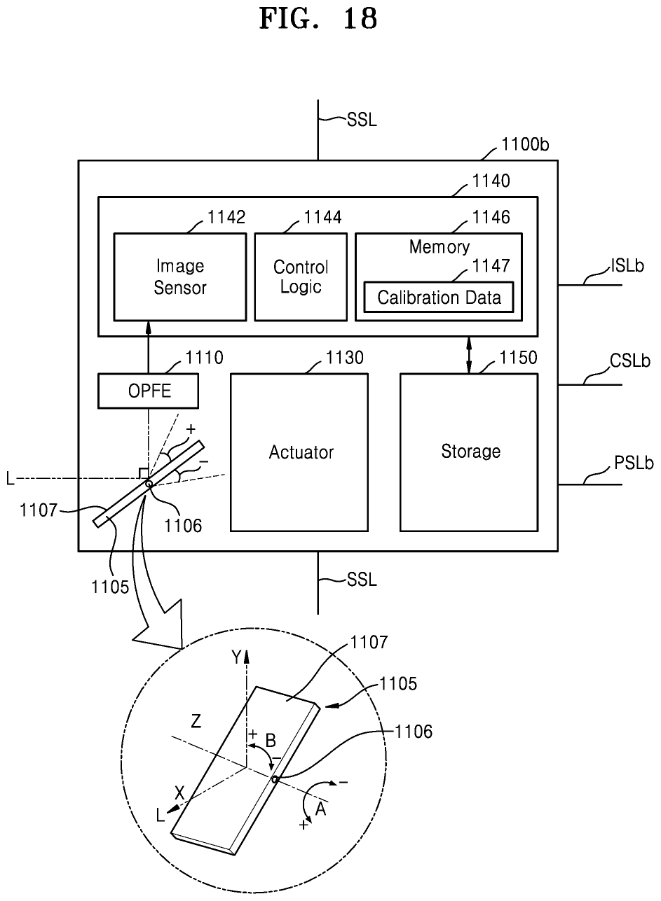

FIG. 17 is a block diagram of an electronic device 1001 including a camera module group 1100, and FIG. 18 is a detailed block diagram of the camera module 1100b in FIG. 17 according to some embodiments.

Referring to FIG. 17, the electronic device 1001 may include the camera module group 1100, an application processor 1200, a PMIC 1300, and an external memory 1400.

The camera module group 1100 may include a plurality of camera modules 1100a, 1100b, and 1100c. Although the drawing illustrates an embodiment in which three camera modules 1100a, 1100b, and 1100c are arranged, the embodiment is not limited thereto. In some embodiments, the camera module group 1100 may include only two camera modules, or may be modified and embodied to include n (wherein n is a natural number 4 or more) camera modules.

Referring to FIG. 18, the camera module 1100b may include a prism 1105, an optical path folding element (OPFE) 1110, an actuator 1130, an image sensing device 1140, and a storage 1150.

In this case, a detailed configuration of the camera module 1100b is described, but the descriptions below may be applied to other camera modules 1100a and 1100c according some to embodiments in the same manner.

The prism 1105 may include a reflective surface 1107 of a light reflecting material, and change a path of light L incident from the outside.

In some embodiments, the prism 1105 may change the path of the light L incident in the first direction (X direction) to the second direction (Y direction) perpendicular to the first direction (X direction). In addition, the prism 1105 may change the path of the light L incident in the first direction (X direction) to the second direction (Y direction) by rotating the reflective surface 1107 of the light reflecting material in a direction A with a center axis 1106 as a center, or rotating the center axis 1106 in a direction B. In this case, the OPFE 1110 may also be moved in the third direction (Z direction) perpendicular to the first direction (X direction) and the second direction (Y direction).

In some embodiments, as illustrated, the maximum rotation angle in the direction A of the prism 1105 may be about 15° or less in a positive (+) direction A, and may be greater than about 15° in a negative (−) direction A, but the embodiments are not limited thereto.

In some embodiments, the prism 1105 may be moved within about 20°, or between about 10° and about 20°, or between about 15° and about 20° in a positive (+) or negative (−) direction B, and in this case, the movement angle may be the same in the positive (+) or the negative (−) direction B, or almost similar angles thereto within a range of about 1°.

In some embodiments, the prism 1105 may move the reflective surface 1107 in the third direction (Z direction) in parallel with an extended direction of the center axis 1106.

The OPFE 1110 may include, for example, an optical lens including m (m is a natural number) groups. The m groups of lenses may move in the second direction (Y direction) and change an optical zoom ratio of the camera module 1100b. For example, when a basic optical zoom ratio of the camera module 1100b is defined as Z, and m groups of optical lenses m included in the OPFE 1110 are moved, the optical zoom ratio of the camera module 1100b may be changed to an optical zoom ratio of 3Z, 5Z, or more.

The actuator 1130 may move the OPFE 1110 or the optical lens to a certain position. For example, the actuator 1130 may adjust a location of the optical lens so that an image sensor 1142 is at a focal length of the optical lens for an accurate sensing.

The image sensing device 1140 may include an image sensor 1142, a control logic 1144, and a memory 1146. The image sensor 1142 may sense an image of a sensing target by using the light L provided via the optical lens. The control logic 1144 may control the overall operation of the camera module 1100b. For example, the control logic 1144 may control an operation of the camera module 1100b according to a control signal provided via a control signal line CSLb.

The memory 1146 may store information required for the operation of the camera module 1100b, such as calibration data 1147. The calibration data 1147 may include information required by the camera module 1100b for generating image data by using the light L provided from the outside. The calibration data 1147 may include, for example, information about the degree of rotation described above, information about the focal length, information about the optical axis, etc. When the camera module 1100b is implemented in a multi-state camera type, in which the focal length varies depending on the position of the optical lens, the calibration data 1147 may include information about a focal length value per position (or per state) of the optical lens and information about auto-focusing.

The storage 1150 may store the image data sensed by the image sensor 1142. The storage 1150 may be arranged outside the image sensing device 1140, and may be implemented in a form, in which the storage 1150 is stacked with a sensor chip constituting the image sensing device 1140. In some embodiments, the storage 1150 may be implemented as an electrically erasable programmable read-only memory (ROM) (EEPROM), but the embodiments are not limited thereto.

Referring to FIGS. 17 and 18 together, in some embodiments, each of the plurality of camera modules 1100a, 1100b, and 1100c may include the actuator 1130. Accordingly, each of the plurality of camera modules 1100a, 1100b, and 1100c may include identical or different calibration data 1147 to or from each other, according to an operation of the actuator 1130 included therein.

In some embodiments, one camera module (for example, 1100b) of the plurality of camera modules 1100a, 1100b, and 1100c may include a folded lens-type camera module including the prism 1105 and the OPFE 1110 described above, and the remaining camera modules (for example, 1100a and 1100c) may include a vertical-type camera module, which does not include the prism 1105 and the OPFE 1110, but the embodiments are not limited thereto.

In some embodiments, one camera module (for example, 1100c) of the plurality of camera modules 1100a, 1100b, and 1100c may include a depth camera of a vertical type, in which depth information is extracted by using, for example, infrared ray (IR). In this case, the application processor 1200 may generate a three-dimensional (3D) depth image by merging image data provided by the depth camera with image data provided by another camera module (for example, 1100a or 1100b).

In some embodiments, at least two camera modules (for example, 1100a and 1100b) of the plurality of camera modules 1100a, 1100b, and 1100c may have different field of views from each other. In this case, for example, the optical lenses of at least two camera modules (for example, 1100a and 1100b) of the plurality of camera modules 1100a, 1100b, and 1100c may be different from each other, but the embodiment is not limited thereto.

In addition, in some embodiments, the field of views of each of the plurality of camera modules 1100a, 1100b, and 1100c may be different from each other. In this case, the optical lenses included in each of the plurality of camera modules 1100a, 1100b, and 1100c may also be different from each other, but the embodiment is not limited thereto.

In some embodiments, each of the plurality of camera modules 1100a, 1100b, and 1100c may be arranged physically spaced apart from each other. In other words, a sensing area of one image sensor 1142 may not be divided and used by the plurality of camera modules 1100a, 1100b, and 1100c, but the image sensor 1142 may be arranged independently inside each of the plurality of camera modules 1100a, 1100b, and 1100c.

Referring again to FIG. 17, the application processor 1200 may include an image processing device 1210, a memory controller 1220, and an internal memory 1230. The application processor 1200 may be implemented to be isolated from the plurality of camera modules 1100a, 1100b, and 1100c. For example, the application processor 1200 and the plurality of camera modules 1100a, 1100b, and 1100c may be implemented to be isolated from each other in isolated semiconductor chips.

The image processing device 1210 may include a plurality of sub-image processors 1212a, 1212b, and 1212c, an image generator 1214, and a camera module controller 1216.

The image processing device 1210 may include the plurality of sub-image processors 1212a, 1212b, and 1212c having the number thereof corresponding to the number of the plurality of camera modules 1100a, 1100b, and 1100c.

The image data generated by each of the plurality of camera modules 1100a, 1100b, and 1100c may be provided to a corresponding plurality of sub-image processors 1212a, 1212b, and 1212c via image signal lines ISLa, ISLb, and ISLc, which are isolated from each other. For example, the image data generated by the camera module 1100a may be provided to the sub-image processor 1212a via an image signal line ISLa, the image data generated by the camera module 1100b may be provided to the sub-image processor 1212b via an image signal line ISLb, and the image data generated by the camera module 1100c may be provided to the sub-image processor 1212c via the image signal line ISLc. Transmission of the image data may be performed by using, for example, a camera serial interface (CSI) based on a mobile industry processor interface (MIPI), but the embodiment is not limited thereto.

On the other hand, in some embodiments, one sub-image processor may also be arranged to correspond to a plurality of camera modules. For example, the sub-image processor 1212a and the sub-image processor 1212c may not be implemented as being isolated from each other as illustrated, but may be implemented as being integrated into one sub-image processor, and the image data provided by the camera module 1100a and the camera module 1100c may, after being selected by a select element (for example, a multiplexer) or the like, be provided to the integrated sub-image processor.

The image data provided to each of the plurality of sub-image processors 1212a, 1212b, and 1212c may be provided to the image generator 1214. The image generator 1214 may generate an output image by using the image data provided by each of the plurality of sub-image processors 1212a, 1212b, and 1212c according to image generating information or a mode signal.

The image generator 1214 may generate an output image by merging at least some of the image data generated by the plurality of camera modules 1100a, 1100b, and 1100c having different field of views from each other, according to the image generation information or the mode signal. In addition, the image generator 1214 may generate an output image by selecting at least one of the image data generated by the plurality of camera modules 1100a, 1100b, and 1100c having different field of views from each other, according to the image generation information or the mode signal.

In some embodiments, the image generating information may include a zoom signal or a zoom factor. In addition, in some embodiments, the mode signal may include, for example, a signal based on a mode selected by a user.

When the image generating information includes the zoom signal or zoom factor, and each of the plurality of camera modules 1100a, 1100b, and 1100c has different field of views from each other, the image generator 1214 may perform different operations from each other according to types of the zoom signals. For example, when the zoom signal includes a first signal, after merging the image data output by the camera module 1100a with the image data output by the camera module 1100c, the image generator 1214 may generate an output image by using the merged image data and the image data output by the camera module 1100b, which has not been used in the merging. When the zoom signal includes a second signal different from the first signal, the image generator 1214 may not perform a merging operation on the image data, but may generate the output image by selecting any one of the image data output by each of the plurality of camera modules 1100a, 1100b, and 1100c. However, the embodiments are not limited thereto, and a method of processing the image data may be modified and performed as necessary.

In some embodiments, by receiving a plurality of image data having different exposure times from each other from at least one of the plurality of sub-image processors 1212a, 1212b, and 1212c, and performing a high dynamic range (HDR) processing on the plurality of image data, the image generator 1214 may generate the merged image data with an increased dynamic range.

The camera module controller 1216 may provide a control signal to each of the plurality of camera modules 1100a, 1100b, and 1100c. The control signal generated by the camera module controller 1216 may be provided to the corresponding plurality of camera modules 1100a, 1100b, and 1100c via control signal lines CSLa, CSLb, and CSLc, which are isolated from each other, respectively.

Any one of the plurality of camera modules 1100a, 1100b, and 1100c may be designated as a master camera module (for example, 1100b) according to the image generating information including the zoom signal or the mode signal, and the other camera modules (for example, 1100a and 1100c) may be designated as slave camera module. These pieces of information may be included in the control signal, and may be provided to the corresponding plurality of camera modules 1100a, 1100b, and 1100c via the control signal lines CSLa, CSLb, and CSLc, which are isolated from each other, respectively.

According to a zoom factor or an operation mode signal, camera modules operating as the master camera module and the slave camera module may be changed. For example, when the field of view of the camera module 1100a is wider than the field of view of the camera module 1100b, and indicates a zoom ratio having a low zoom factor, the camera module 1100b may operate as the master camera module, and the camera module 1100a may operate as the slave camera module. On the other hand, when the field of view of the camera module 1100a indicates a zoom ratio having a high zoom ratio, the camera module 1100a may operate as the master camera module, and the camera module 1100b may operate as the slave camera module.

In some embodiments, the control signal provided by the camera module controller 1216 to each of the plurality of camera modules 1100a, 1100b, and 1100c may include a sync enable signal. For example, when the camera module 1100b is the master camera module, and the camera modules 1100a and 1100c are the slave camera modules, the camera module controller 1216 may transmit the sync enable signal to the camera module 1100b. The camera module 1100b having received the sync enable signal may generate a sync signal based on the received sync enable signal, and provide the generated sync signal to the camera modules 1100a and 1100c via a sync signal line SSL. The camera module 1100b and the camera modules 1100a and 1100c may be synchronized to the sync signal, and transmit the image data to the application processor 1200.

In some embodiments, the control signal provided by the camera module controller 1216 to the plurality of camera modules 1100a, 1100b, and 1100c may include mode information according to the mode signal. Based on the mode information, the plurality of camera modules 1100a, 1100b, and 1100c may operate in a first operation mode and a second operation mode with respect to a sensing speed.

The plurality of camera modules 1100a, 1100b, and 1100c may, in the first operation mode, generate the image signal at a first speed (for example, generate the image signal at a first frame rate), encode the generated image signal at a second speed higher than the first speed (for example, encode the generated image signal at a second frame rate greater than the first frame rate), and transmit the encoded image signal to the application processor 1200.

The application processor 1200 may store the received image signal, that is, the encoded image signal, in the internal memory 1230 equipped therein or in the external memory 1400 outside the application processor 1200, and then, may read and decode the encoded image signal from the internal memory 1230 or the external memory 1400, and may display the image data, that is generated based on the decoded image signal. For example, a sub-image processor corresponding to the plurality of sub-image processors 1212a, 1212b, and 1212c of the image processing device 1210 may perform decoding, and in addition, may perform an image processing on the decoded image signal.

The plurality of camera modules 1100a, 1100b, and 1100c may, in the second operation mode, generate the image signal at a third speed lower than the first speed (for example, generate the image signal at a third frame rate less than the first frame rate), and transmit the image signal to the application processor 1200. The image signal provided to the application processor 1200 may include an un-encoded signal. The application processor 1200 may perform the image processing on the received image signal, or store the received image signal in the internal memory 1230 or the external memory 1400.

The PMIC 1300 may provide power, for example, a power voltage to each of the plurality of camera modules 1100a, 1100b, and 1100c. For example, the PMIC 1300 may, under the control of the application processor 1200, provide a first power to the camera module 1100a via a power signal line PSLa, provide a second power to the camera module 1100b via a power signal line PSLb, and provide a third power to the camera module 1100c via a power signal line PSLc.

The PMIC 1300 may, in response to a power control signal PCON from the application processor 1200, generate power corresponding to each of the plurality of camera modules 1100a, 1100b, and 1100c, and in addition, may adjust a level of the generated power. The power control signal PCON may include a power adjustment signal per operation mode of the plurality of camera modules 1100a, 1100b, and 1100c. For example, the operation mode may include a low power mode, and in this case, the power control signal PCON may include information about a camera module operating at the low power mode and information about a set power level. The levels of power provided to each of the plurality of camera modules 1100a, 1100b, and 1100c may be identical to or different from each other. In addition, the level of power may be dynamically changed.

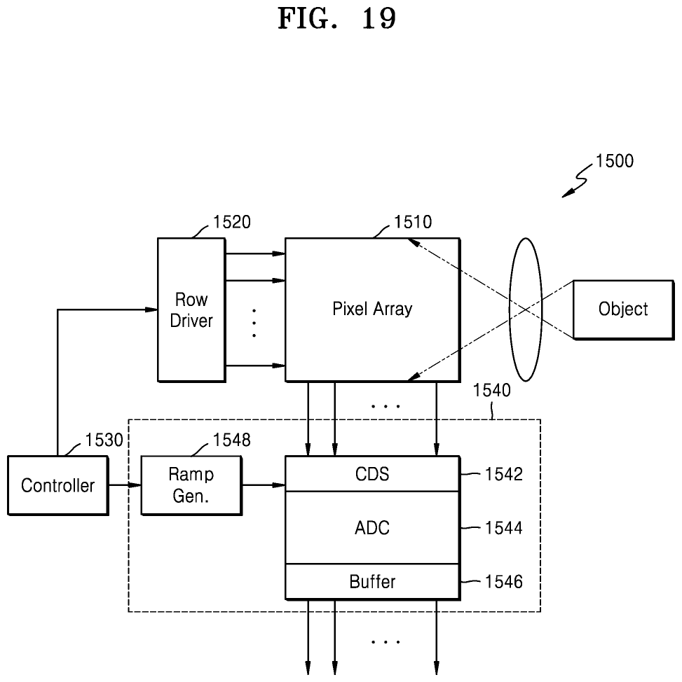

FIG. 19 is a block diagram of an image sensor 1500 according to some embodiments.

Referring to FIG. 19, the image sensor 1500 may include a pixel array 1510, a controller 1530, a row driver 1520, and a pixel signal processor 1540.

The image sensor 1500 may include the image sensor 1000 described above. The pixel array 1510 may include a plurality of unit pixels PX arranged two-dimensionally, and each unit pixel PX may include a photoelectric conversion element. The photoelectric conversion element may absorb light to generate photo charges, and an electrical signal (or an output voltage) according to the generated photo charges may be provided to the pixel signal processor 1540 via a vertical signal line.

The unit pixels PX included in the pixel array 1510 may provide one output voltage at a time in row units, and accordingly, the unit pixels PX belonging to one row of the pixel array 1510 may be simultaneously activated by a select signal, which is output by the row driver 1520. The unit pixel PX belonging to the selected row may provide the output voltage corresponding to the absorbed light to an output line of a corresponding column.

The controller 1530 may control the row driver 1520 so that the pixel array 1510 absorbs light to accumulate the photo charges, or temporarily store the accumulated photo charges, and outputs an electrical signal corresponding to the stored photo charges to the outside thereof. In addition, the controller 1530 may control the pixel signal processor 1540 to measure the output voltage provided by the pixel array 1510.

The pixel signal processor 1540 may include a correlated double sampler (CDS) 1542, an analog to digital converter (ADC) 1544, and a buffer 1546. The CDS 1542 may sample and hold the output voltage provided by the pixel array 1510.

The CDS 1542 may double-sample a certain noise level and a level of the generated output voltage, and output a level corresponding to a difference therebetween. In addition, the CDS 1542 may receive ramp signals generated by a ramp signal generator (Ramp Gen.) 1548, compare the ramp signals to each other, and output a result of the comparison.

The ADC 1544 may convert an analog signal corresponding to the level received from the CDS 1542 into a digital signal. The buffer 1546 may latch the digital signal, and the latched digital signal may be sequentially output to the outside of the image sensor 1500 and transferred to an image processor (not illustrated).

As used herein, an element or region that is “covering” or “surrounding” or “filling” another element or region may completely or partially cover or surround or fill the other element or region.

Although terms (e.g., first, second or third) may be used herein to describe various elements, these elements should not be limited by these terms. These terms are only used to distinguish one element from another. For example, a first element may be referred to as a second element, and, similarly a second element may be referred to as a first element without departing from the teachings of the disclosure. As used herein, the term “and/or” includes any and all combinations of one or more of the associated listed items.

While the inventive concept has been particularly shown and described with reference to embodiments thereof, it will be understood that various changes in form and details may be made therein without departing from the scope of the following claims.

What is claimed is:

1. An image sensor comprising:
a semiconductor substrate including a first pixel and a second pixel adjacent to the first pixel;
a pixel isolation structure between the first pixel and the second pixel;
an anti-reflection layer on the first pixel, the second pixel, and the pixel isolation structure; and
a through via structure in a through via hole that is in the anti-reflection layer and the semiconductor substrate,
wherein the through via structure comprises:
a first conductive layer extending on an inner wall of the through via hole; and
a second conductive layer extending on the first conductive layer on the inner wall of the through via hole, and
wherein the anti-reflection layer comprises TiO₂, and
the first conductive layer comprises a material having a higher work function than Ti.

2. The image sensor of claim 1, wherein the first conductive layer comprises WN, TiN and/or TaN.

3. The image sensor of claim 1, wherein the semiconductor substrate comprises a first surface and a second surface opposite to the first surface,
the anti-reflection layer is on the second surface, and
the through via structure extends through the semiconductor substrate from the second surface to the first surface.

4. The image sensor of claim 1, further comprising a first dark current suppression layer that is between the semiconductor substrate and the anti-reflection layer,
wherein the first dark current suppression layer comprises aluminum oxide and/or hafnium oxide.

5. The image sensor of claim 4, further comprising an insulating layer on the anti-reflection layer,
wherein the insulating layer comprises silicon oxide.

6. The image sensor of claim 1, wherein the through via structure is free of Ti.

7. The image sensor of claim 1, further comprising:
a first front structure on a first surface of the semiconductor substrate; and
a second front structure contacting the first front structure,
wherein the through via structure comprises a first portion in the first front structure and a second portion in the second front structure.

8. The image sensor of claim 7, wherein the first front structure comprises a first conductive pattern,
wherein the second front structure comprises a second conductive pattern, and
wherein the through via structure electrically connects the first conductive pattern to the second conductive pattern.

9. The image sensor of claim 1, wherein the first conductive layer contacts a side surface of the anti-reflection layer.

10. The image sensor of claim 1, wherein the first conductive layer comprises a material having a work function greater than 4.33 eV.

11. The image sensor of claim 1, wherein the first conductive layer extends on a portion of an upper surface of the anti-reflection layer, and
the through via structure has a width decreasing with an increasing depth of the through via hole.

12. An image sensor comprising:
a semiconductor substrate including a first pixel and a second pixel adjacent to the first pixel;
a pixel isolation structure between the first pixel and the second pixel;
an anti-reflection layer on the first pixel, the second pixel, and the pixel isolation structure;
a first front structure on a first surface of the semiconductor substrate and including a first conductive pattern;
a second front structure contacting the first front structure and including a second conductive pattern; and
a through via structure in a through via hole that extends through the anti-reflection layer and the semiconductor substrate, wherein the through via structure includes a first portion in the first front structure and a second portion in the second front structure and electrically connects the first conductive pattern to the second conductive pattern,
wherein the through via structure comprises:
a first conductive layer extending on an inner wall of the through via hole; and
a second conductive layer extending on the first conductive layer on the inner wall of the through via hole, and
the first conductive layer includes nitride, and the second conductive layer includes tungsten.

13. The image sensor of claim 12, wherein the first conductive layer comprises metal nitride including W, Ti and/or Ta.

14. The image sensor of claim 12, wherein the first conductive layer contacts a side surface of the anti-reflection layer, and
the second conductive layer is spaced apart from the anti-reflection layer.

15. The image sensor of claim 12, wherein the second conductive layer is in contact with the first conductive layer.

16. The image sensor of claim 12, wherein the semiconductor substrate further comprises a second surface opposite to the first surface,
wherein the image sensor further comprises:
a first dark current suppression layer between the second surface of the semiconductor substrate and the anti-reflection layer;
a second dark current suppression layer on the anti-reflection layer; and
an insulating layer between the second dark current suppression layer and the anti-reflection layer,
wherein the first dark current suppression layer and the second dark current suppression layer each comprise aluminum oxide and/or hafnium oxide, and
the insulating layer comprises silicon oxide.

17. The image sensor of claim 16, wherein the through via structure contacts a side surface of each of the first dark current suppression layer, the second dark current suppression layer, and the insulating layer.

18. An image sensor comprising:
a first semiconductor chip including a first semiconductor substrate, on which logic elements are provided, and a first front structure on the first semiconductor substrate;
a second semiconductor chip including a second semiconductor substrate stacked on the first semiconductor chip and including a plurality of pixels, an anti-reflection layer on the second semiconductor substrate, and a second front structure under the second semiconductor substrate; and
a through via structure that is in the anti-reflection layer, the second semiconductor substrate and the second front structure and electrically connects the logic elements to the plurality of pixels,
wherein the anti-reflection layer comprises TiO₂,
the through via structure comprises a second conductive layer including tungsten and a first conductive layer including a material having a higher work function than Ti, and
wherein the first conductive layer contacts a side surface of the anti-reflection layer.

19. The image sensor of claim 18, wherein the first conductive layer comprises WN, TiN and/or TaN,
the second conductive layer is spaced apart from the anti-reflection layer and contacts the first conductive layer, and
the anti-reflection layer is free of HfO 2.

20. The image sensor of claim 18, wherein the first front structure comprises a first conductive pattern, and the second front structure comprises a second conductive pattern, and
wherein the first conductive layer contacts the first conductive pattern and the second conductive pattern.
